(19) United States
(12) Patent Application Publication
(10) Pub. No.: US 2013/0193290 A1
(43) Pub. Date: Aug. 1, 2013

(54) Low-profile quick-adjust mount for laptop computer

(71) Applicant: Sara M. Lohmann, Ithaca, NY (US)

(72) Inventor: Sara M. Lohmann, Ithaca, NY (US)

(73) Assignee: United States Government, as represented by the Secretary of the Navy, Arlington, VA (US)

(21) Appl. No.: 13/385,464

(22) Filed: Jan. 31, 2012

(51) Int. Cl. H05K 7/00

(52) U.S. Cl. 248/276.1

(57) ABSTRACT

A mount is provided for removably attaching a laptop computer releasably connected to a platform in a vehicle. The mount includes a handle, an interface bay, a pivot plate, a plurality of holders, and a collar. The handle mounts to the vehicle. The interface bay removably attaches to the platform onto which the computer mounts. The pivot plate mounts to the bay. Each of the holders wraps around the handle and attaches to the pivot plate. The collar releasably secures the pivot plate at an angle relative to vehicle horizontal. The platform can rotate in pitch relative to the handle and can pivot in roll relative to the pivot plate.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

The invention relates generally to a computer laptop mount. In particular, the invention relates to an adjustable mount on a moving vehicle for supporting a laptop computer.

The United States Marine Corps employs the Growler, an internally transportable vehicle (ITV) for ground mobility in field operations, capable of being ferried aboard the MV-22. Various missions involve use of a ruggedized computer laptop such as the Toughbook-19 from Panasonic®. The conventional mount for this laptop was originally designed for use by the front passenger in an ITV with limited options for mounting. The front handle bar was determined to be the optimal location for conventional mounting.

### SUMMARY

Conventional laptop mounts for a vehicle yield disadvantages addressed by various exemplary embodiments of the present invention. In particular, various exemplary embodiments provide mount for removably attaching a laptop computer in a vehicle. The mount includes a handle, a platform, an interface bay, a pivot plate, a plurality of holders, and a collar. The handle mounts to the vehicle. The platform releasably attaches to the laptop computer. The interface bay removably attaches to the platform. The pivot plate mounts to the bay. Each of the holders wraps around the handle and attaches to the pivot plate.

The collar releasably secures the pivot plate at an angle relative to vehicle horizontal. The platform can rotate in pitch relative to the handle and can pivot in roll relative to the pivot plate. In various exemplary embodiments, the collar further includes plurality of lock settings for a position for said platform oriented at one of +90°, −5°, −20° and −90° from vehicle horizontal

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is an isometric assembly view of an adapter for a laptop in a first embodiment;

FIGS. 2A through 2E are elevation assembly views of the adapter;

FIG. 3 is an isometric assembly view of the adapter;

FIG. 4 is an isometric exploded view of adapter components;

FIG. 5 is an isometric assembly view showing rotation modes;

FIG. 6 is an isometric view of a laptop;

FIG. 7 is an isometric view of a platform;

FIGS. 8A and 8B are isometric exploded views of a dock;

FIG. 9 is an isometric exploded view of the platform and dock;

FIG. 10 is an isometric exploded view of the adapter components;

FIG. 11 is an isometric assembly view of adapter portions for a second embodiment;

FIGS. 12A and 12B are isometric exploded views of the adapter;

FIGS. 13 and 14 are isometric detail views of laptop and platform; and

FIGS. 15A through 15E are perspective views of the adapter assembly as installed in the dashboard of a military vehicle.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

The requirements for laptop computer usage included being in a vertical position for the tablet mode and two other positions having an oblique angle slightly depressed from horizontal for the open (or typing) mode. For purposes of this disclosure, horizontal and vertical orientations are defined relative to the vehicle. The lower of the two depressed positions can also be used in tablet mode.

Due to the limited room in the ITV, the laptop must in the vertical position for the passenger to exit. Therefore, a key functionality includes enabling the laptop to quickly move from a horizontal position to a vertical position. Another constraint concerns positioning the laptop in a vertical down orientation as necessary so that while the ITV is in the MV-22, the driver can exit over the hood. Commercial-off-the-shelf (COTS) adjustable laptop mounts are bulky and difficult to position. With limited space and difficult constraints, there was a need for a custom low-profile quick-adjust laptop mount.

Various exemplary embodiments provide an adjustable laptop mount that can be removably installed aboard a motor vehicle, such as the ITV, or alternate moving platforms. The mount can be adjusted to enable the laptop to swivel about a roll axis to enable the screen to be turned around, as well as to pivot in pitch along the axis of a mounting bar.

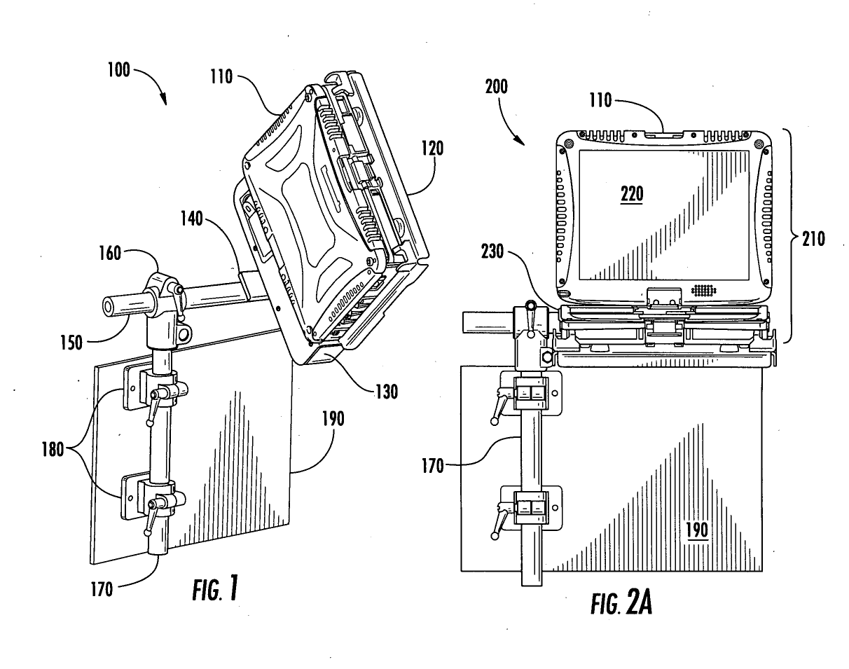

FIG. 1 shows an isometric assembly view 100 of a first embodiment of a vehicle mount adapter for a laptop 110, such as a Panasonic® Toughbook CF19 (configurable as a touch-screen tablet or notebook personal computer), to be mounted to cylindrical protrusion in a motor vehicle. The adapter assembly includes a laptop base platform 120 onto which the laptop 110, depicted in closed configuration, attaches. An interface docking bay or dock 130 connects to the platform 120. A pivot mount 140 attaches to the dock 130. The mount 140 can be removably connected to a bar that protrudes in the vehicle, in particular in association with a rear passenger seat.

For the first exemplary embodiment, a transverse tube 150, which extends substantially horizontally in the vehicle, represents the bar. The transverse tube 150 connects by a rotation joint 160 to a lateral tube 170. Cinch connectors 180 secure the lateral tube 170 to a support plate 190 mounted in the vehicle. The adapter constitutes the assembly that secures the laptop 110 in position as part of a low-profile quick-adjust laptop mount (LQALM) for installation in a vehicle.

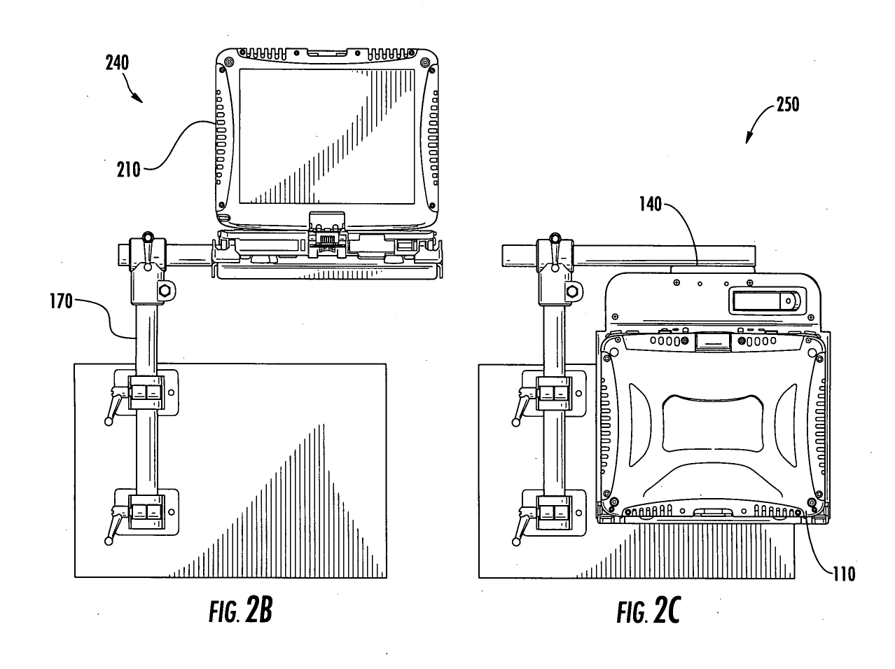

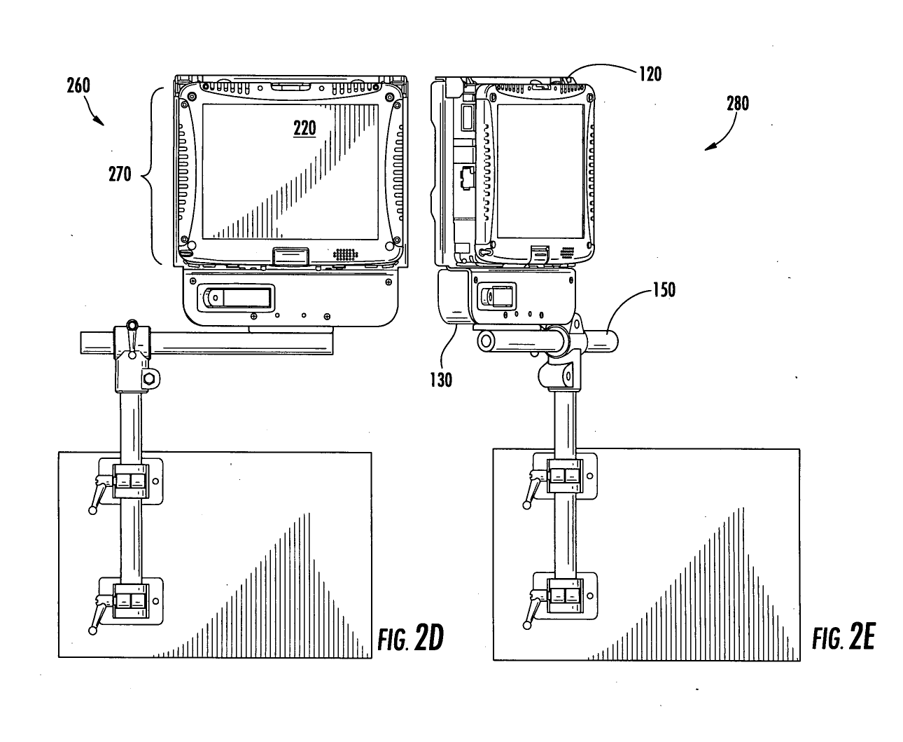

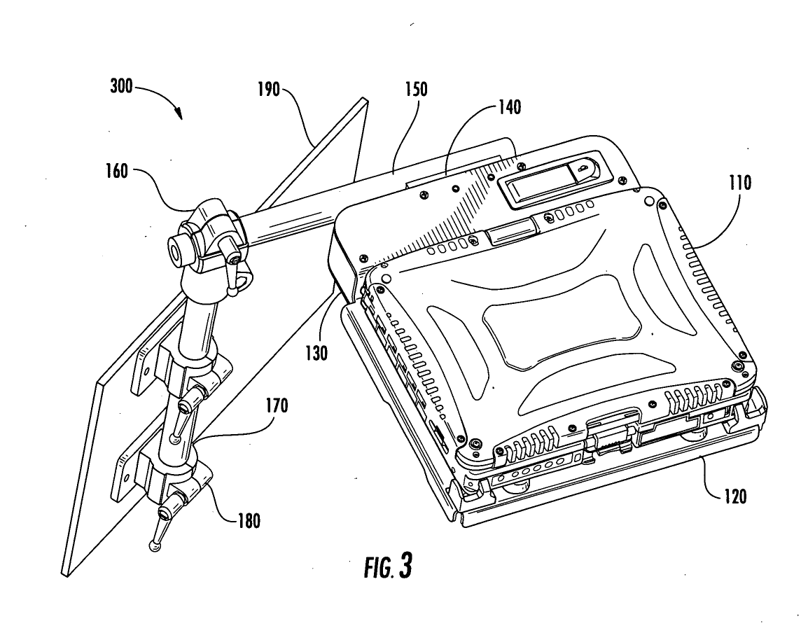

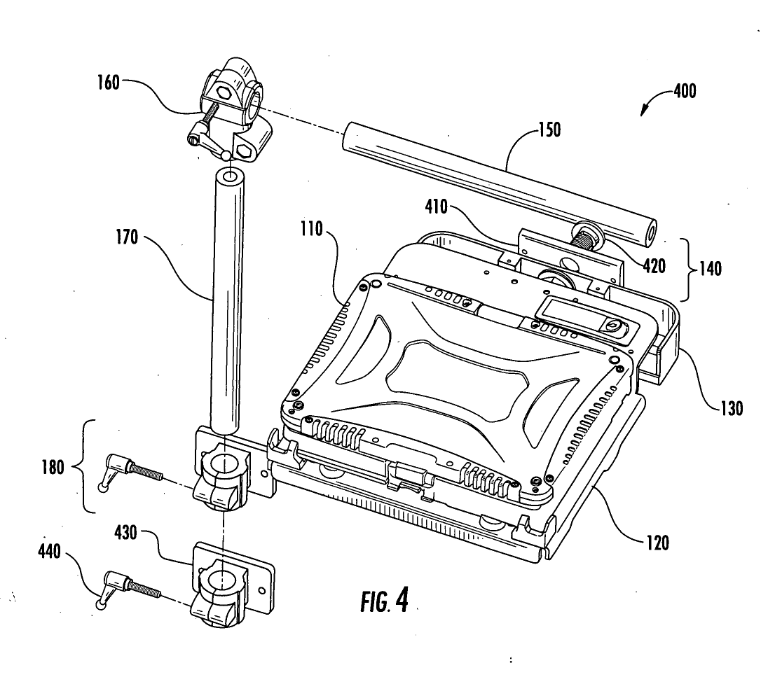

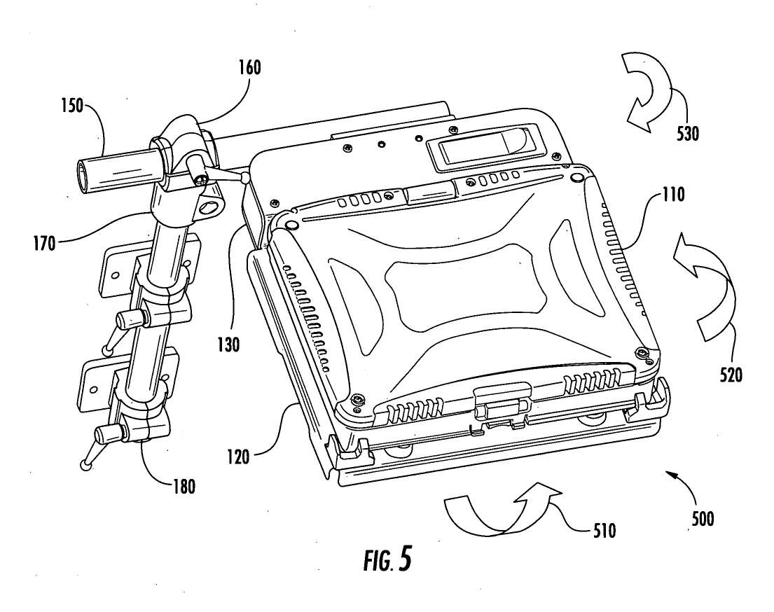

FIGS. 2A through 2E show elevation assembly views of the adapter assembly. FIG. 2A illustrates a first elevation view 200 showing the laptop 110 in an open configuration 210, thereby exposing a screen display 220 and a keyboard 230 available for operation in the vehicle, and the lateral tube 170 depressed. FIG. 2B shows a second elevation view 240 with the open laptop 210 and the lateral tube 170 raised so as to elevate the transverse tube 150 and the platform 120 that supports the laptop.

FIG. 2C shows a third elevation view 250 that shows the laptop 110 in the closed configuration pivoted on the mount 140 to orient downward facing towards the plate 190. FIG. 2D shows a fourth elevation view 260 that shows the laptop 110 in a tablet mode 270 with the display 220 blocking the keyboard 230, such as for navigation or touch-screen operation. FIG. 2E shows a fifth elevation view 280 in tablet mode 270 with the transverse tube 150 turned (counter-clockwise) along the axis of the lateral tube 170 to orient the display 220 facing towards one side (starboard, in this example).

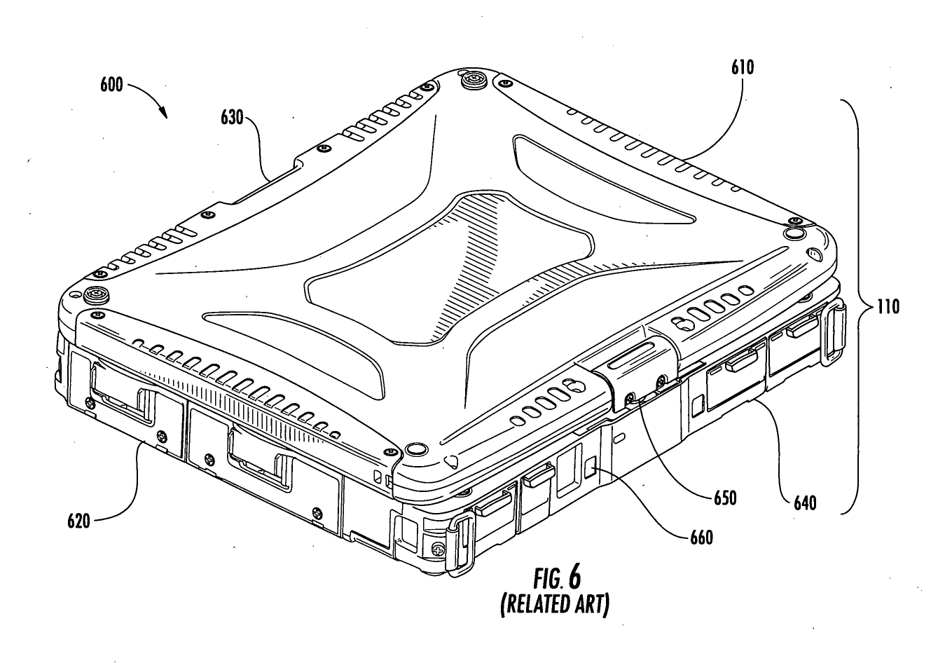

FIG. 3 shows an isometric assembly view 300 of the adapter as observed from above. The laptop 110 (closed) attaches to the platform 120, which connects to the dock 130. The mount 140 pivotably connects the dock 130 to the transverse tube 150. The lateral tube 170 attaches to the support plate 190 (representative of a surface in the vehicle) by the cinch connectors 180 and pivotably to the transverse tube 150 by the joint 160.

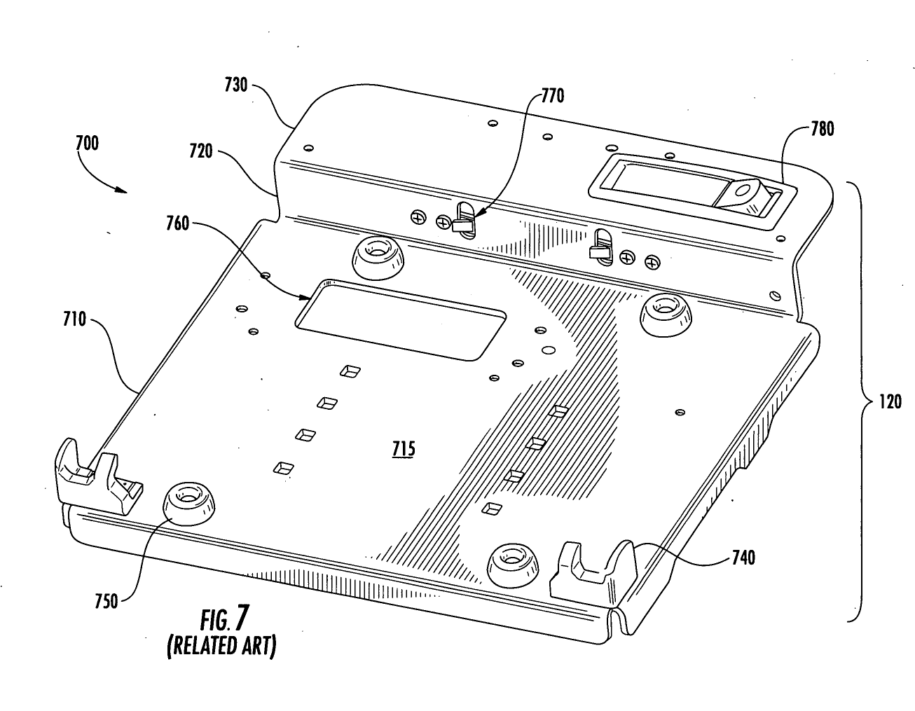

FIG. 4 illustrates an isometric exploded view 400 of the adapter with the laptop 110 (closed) attached to the platform 120. The dock 130 is shown separated from the platform 120 and to the mount 140, which includes a plate 410 and a bolt 420 to be subsequently described in further detail. The transverse and lateral tubes 150 and 170 are depicted separate from their joint 160. The connectors 180 are shown below the lateral tube 170, each including a sleeve flange 430 and a cinch knob 440.

FIG. 5 shows an isometric assembly view 500 of the adapter with the laptop (closed) attached to the platform 120 observable in a similar orientation as the view 300. The platform 120 and associated laptop 110 can pivot in pitch, shown by arrow 510, and in roll, shown by arrow 520. The joint 160 enables the transverse tube 150 to rotate in yaw, shown by arrow 530. Pivot motions in these directions can be continuous, although rigid positioning at set angles can be provided by various locking mechanisms.

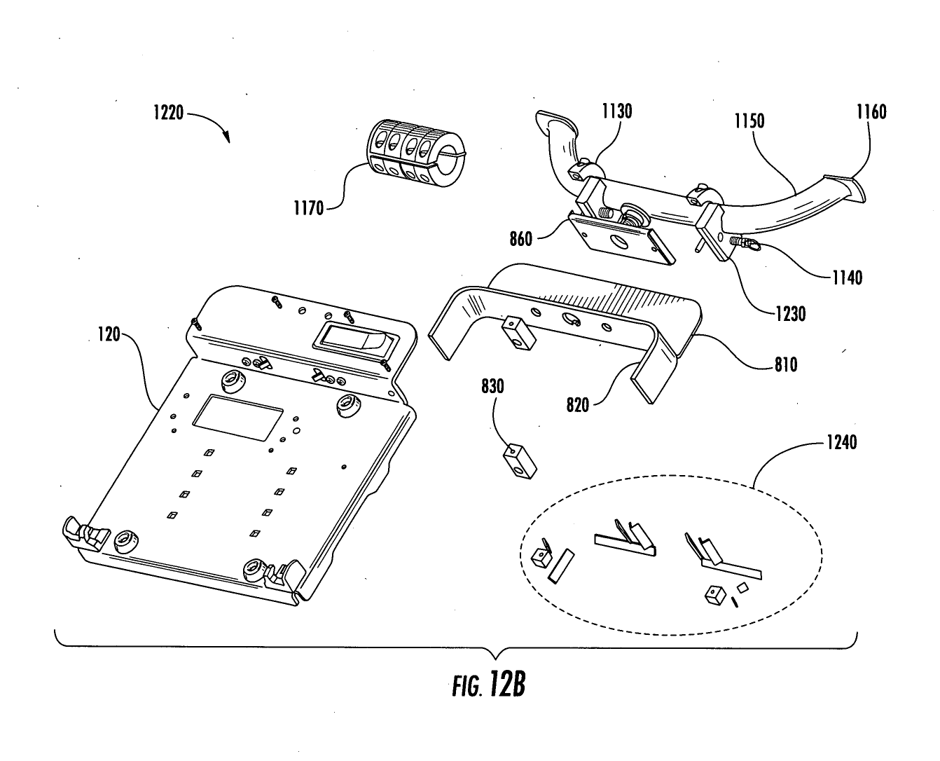

The mount 140 enables the laptop 110 to roll (arrow 520). When grip releasing the joint 160 on the transverse tube 150, the laptop 110 can translate along the axis of that tube 150 as well as rotate in pitch (arrow 510). The lateral tube 170 statically connects to the joint 160. Grip release of the two cinch connectors 180 enables the lateral tube 170 to move vertically along the axis of that tube 170 and to rotate in yaw (arrow 530) about the lateral tube's axis. In the handle bar. configuration (FIG. 11), the mount 140 can be used for rotation in both pitch and roll.

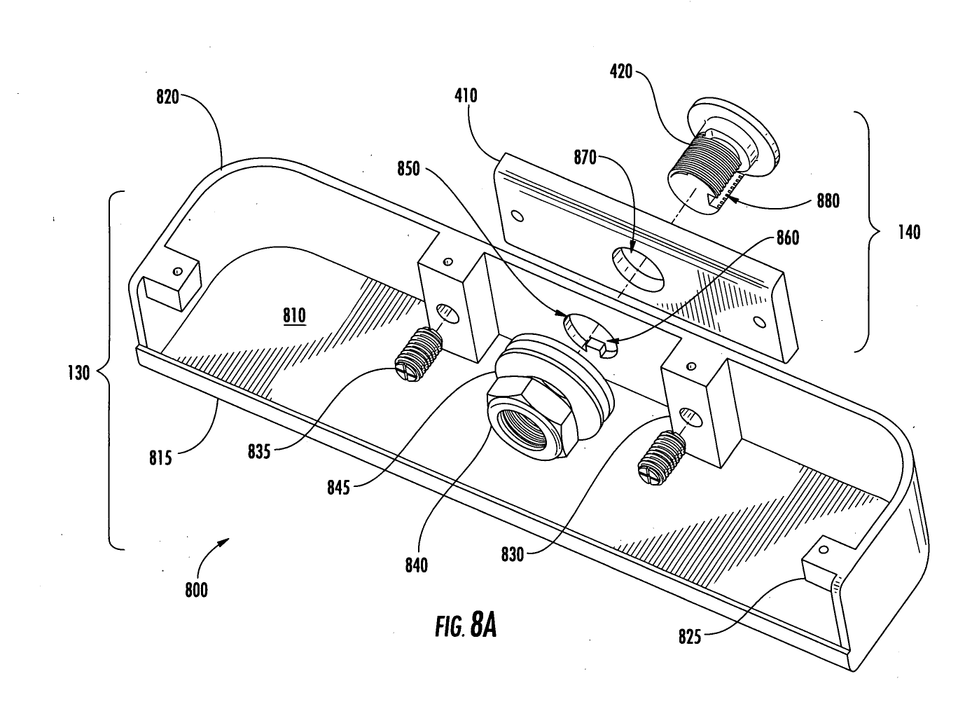

FIG. 6 shows an isometric view 600 of a Toughbook-19 as the laptop 110 in closed configuration from the port and aft sides. An upper monitor cover 610 houses the screen display 220 and a lower frame 620 houses the keyboard 230 with the frame bounded by front and rear sides 630 and 640. The front side 630 includes a latch for releasing the upper cover 610 to pivotably open on the hinge 650 at the rear side 640, thereby revealing the display 220 and the keyboard 230 for operational use. A pair of cutouts 660 recess into the rear side 640 for releasing the laptop 110 from the platform 120.

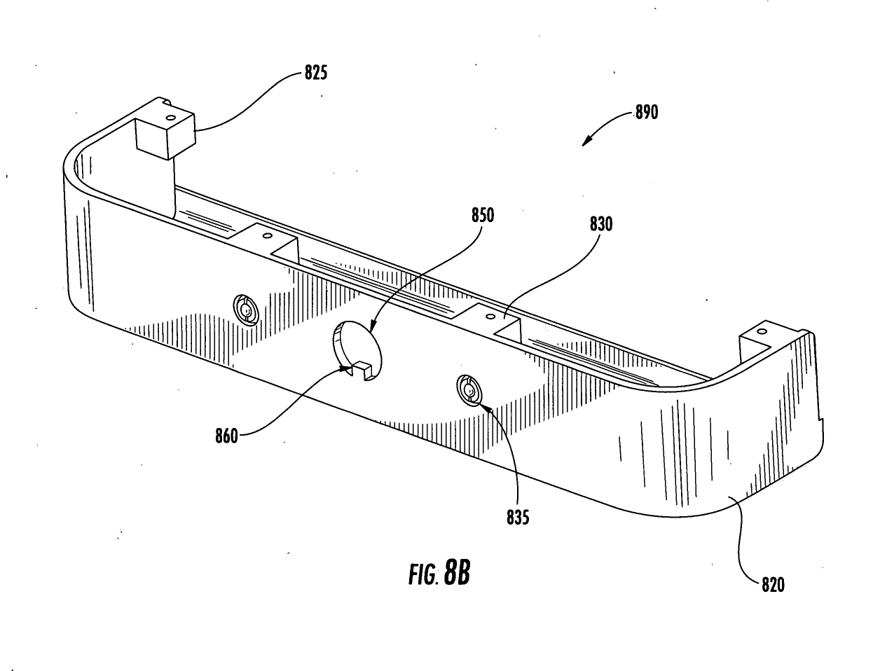

FIG. 7 shows an isometric view 700 of the base platform 120 based on the Gamber-Johnson laptop cradle. The platform 120 is substantially formed from a folded sheet metal plate with a base 710 that exhibits a flat surface 715, a shoulder 720 and a mesa or table 730. Corner foot restraints 740 and elastic shims 750 are disposed on the surface 715. Tangs 770 (with vertically oriented prongs) protrude through the shoulder 720 for securing to the laptop 110. The table 730 includes a latch 780 for releasing the laptop 110 from the feet 740.

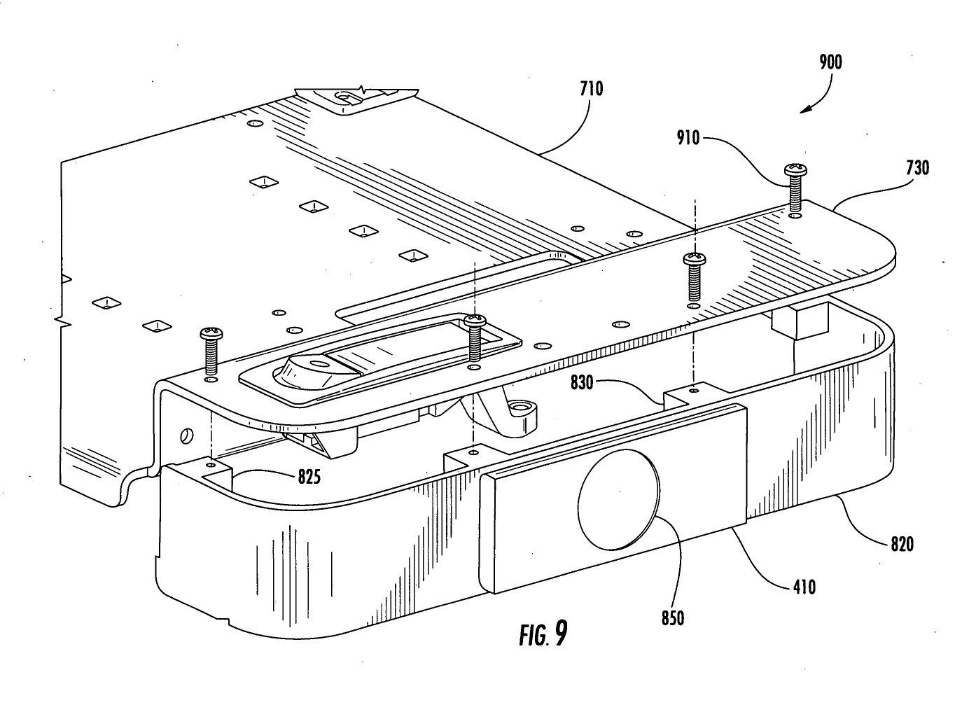

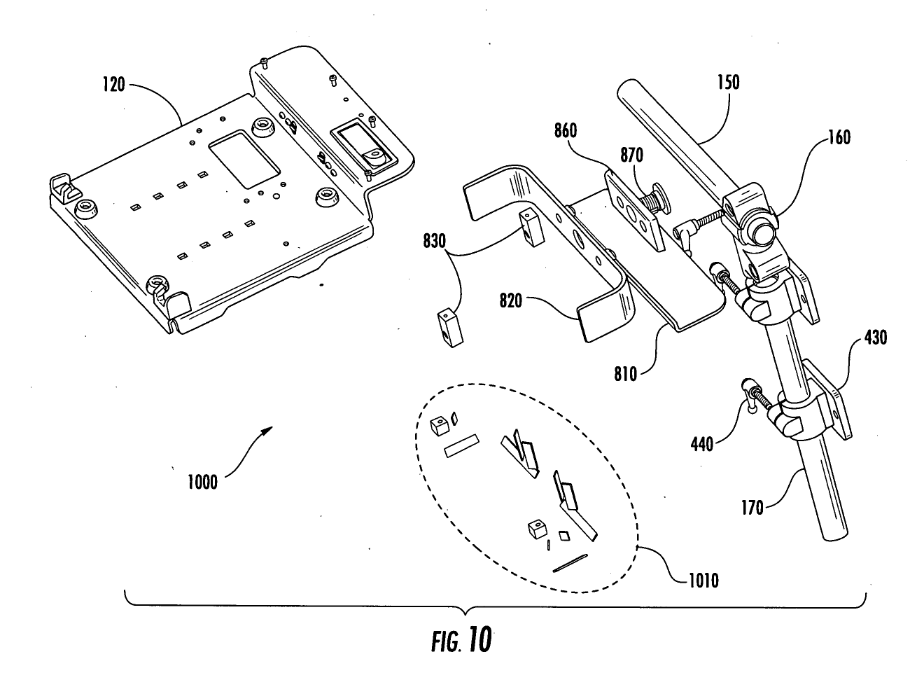

FIG. 8A shows an isometric exploded view 800 of the dock 130. A dock floor 810 bounded by an edge lip 815 connects to a boundary wall 820. The floor 810 and wall 820 can constitute a unitary item or alternatively represent separate components subsequently secured together. The wall 820 includes corner tabs 825 and blocks 830, the latter having orifices for receiving threaded detents 835.

The dock 130 attaches to the mount plate 410 by a threaded nut 840 that engages the threaded bolt 420. One or more washers 845 separate the nut 840 from contact with the wall 820, aligned along the wall 820 with an orifice 850 having a tooth 860. The bolt 420 passes through a through-hole 870 of the plate 410 and through the orifice 850 with an axial notch 880 aligned with the tooth 860. FIG. 8B shows an isometric view 890 of the dock 130 from the rear, with the detents 835 protruding visibly through orifices in the blocks 830.

The laptop platform 120 utilizes the geometry of a laptop cradle from Gamber-Johnson® LLC of Stevens Point, Wisconsin (Dual RF Docking Station, manufacturing part 7160-0207-02). The plastic portion of the Gamber-Johnson station is replaced with ITV-FL-05. This custom designed platform 120 utilizes the empty space in the Gamber-Johnson dock for the roll mechanism.

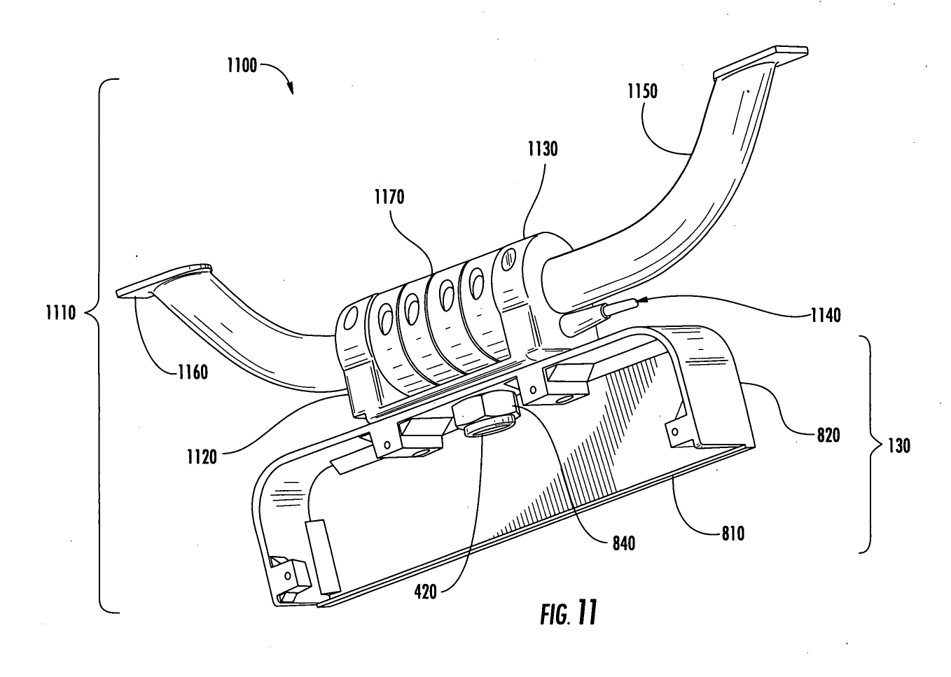

FIG. 9 shows an isometric exploded view 900 of the base platform 120 and the dock 130. The table 730 includes holes along the boundary that align with the tabs 825 and the blocks 830 to secure each other by screws 910.

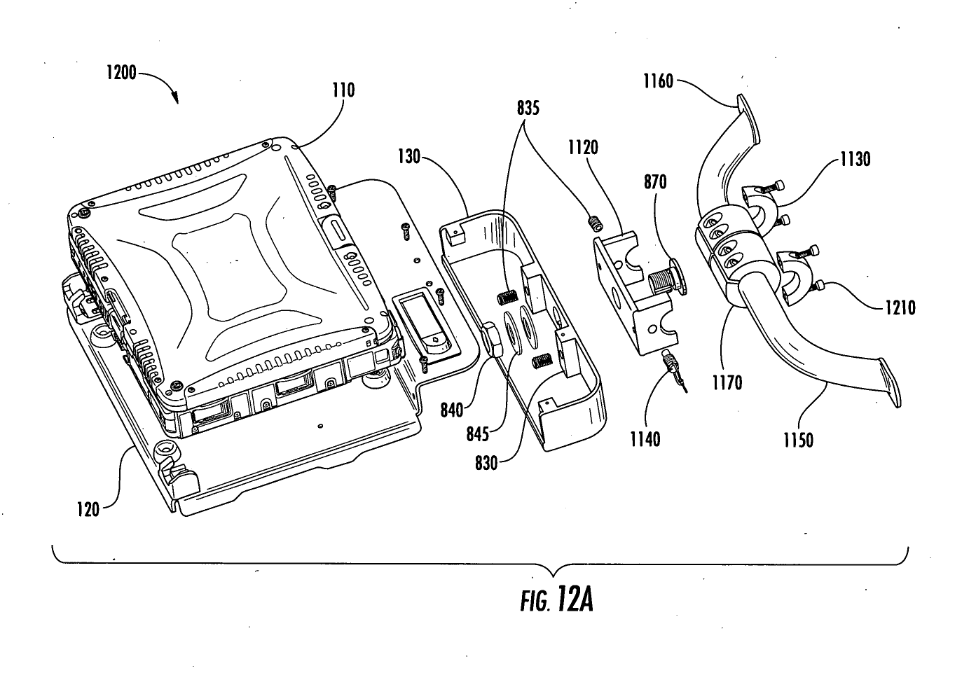

FIG. 10 shows an isometric exploded view 1000 of the adapter. In particular, the dock 130 is exhibited with the floor 810, wall 820 and blocks 830 separated as distinct components, although alternatively, these items can be combined into a single piece unit. Supplemental attach components 1010 can also be employed.

FIG. 11 shows an isometric assembly view 1100 in the second embodiment of select components of the adapter as intended for a dashboard at the front of the passenger compartment. The assembly 1110 as shown represents the dashboard adapter, not including the platform 120. The dock 130 attaches via the bolt 420 and nut 840 to a block 1120 with semicircular channels, each end of which connects to a corresponding half-ring 1130. A plunger 1140 inserts into the block 1120 to restrict pitch rotation of the dock 130.

The block 1120 and half-rings 1130 together clamp around a handlebar 1150 that connects to a dashboard by flush-mount flanges 1160 at each end. A split-cylindrical fixed shaft collar 1170 provides a releasable locking mechanism to restrict rotation to a set pitch among several available angular positions from which to select, subject to insertion of the plunger 1140 into the block 1110. The plunger 1140 can be spring-load connected to the block 1120 with a lanyard attached to its distal end for pulling convenience to release the collar 1170.

FIGS. 12A and 12B show isometric exploded views of the second embodiment of the adapter for the dashboard. FIG. 12A provides an exploded view 1200 with the laptop 110. Three detents 835 are shown—a pair for the blocks 830 and a remaining one on the block 1120 opposite the plunger 1140. The half-rings 1130 attach to the block 1120 by screws 1210. FIG. 12B provides an exploded view 1220 showing an empty platform 120. In an alternate configuration, the half-rings 1130 clamp around the handlebar 1150 by attaching to corresponding braces 1230 at either side of the collar 1170. Additional components 1240 can be provided for associating components together.

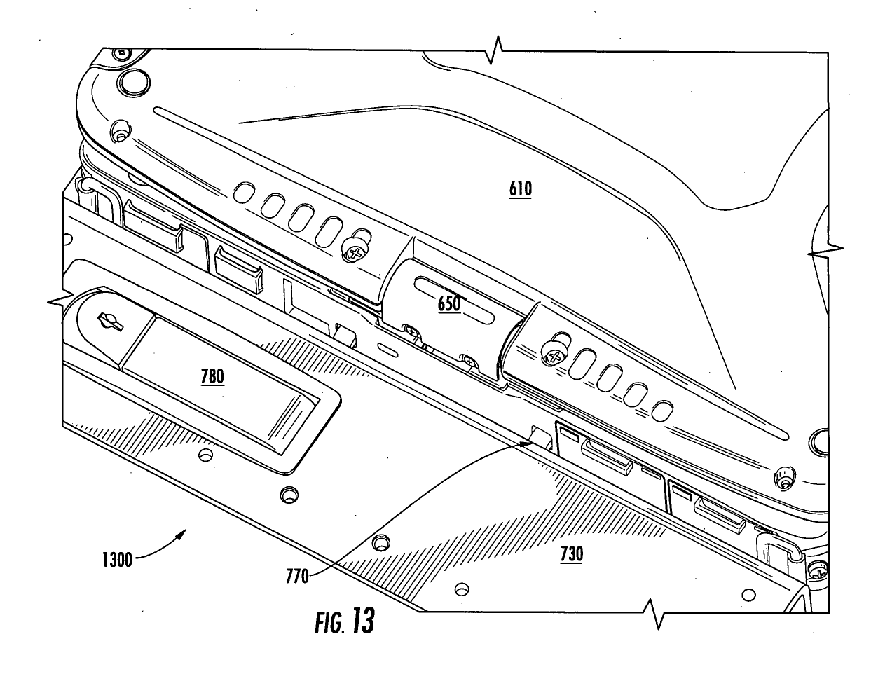

FIG. 13 shows an isometric detail view 1300 from above the laptop 110 and the base platform 120, showing the tangs 770 flanking behind the hinge 650, and the latch 780 disposed on the table 730. The tangs 770 protrude into and engage the cutouts 660 on the laptop 110.

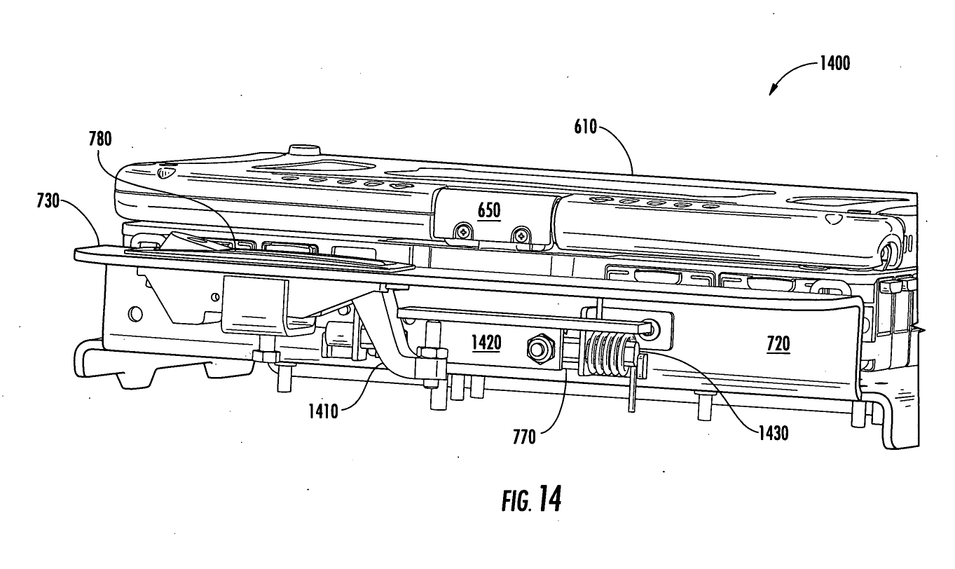

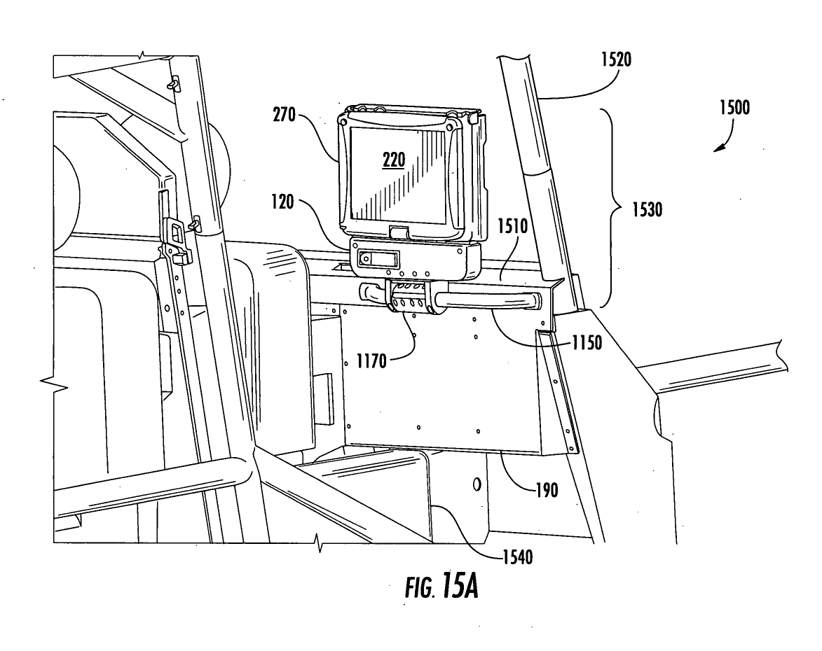

FIG. 14 shows an isometric detail view 1400 from behind the laptop 110 and the base platform 120. A lever arm 1410 connects to the latch 780 for releasing the laptop 110 from being wedged against the corner feet 740 by pressing an endplate 1420, which includes spring-loaded pegs 1430 that wedge against the tangs 770 for securing the laptop 110 to the platform 120.

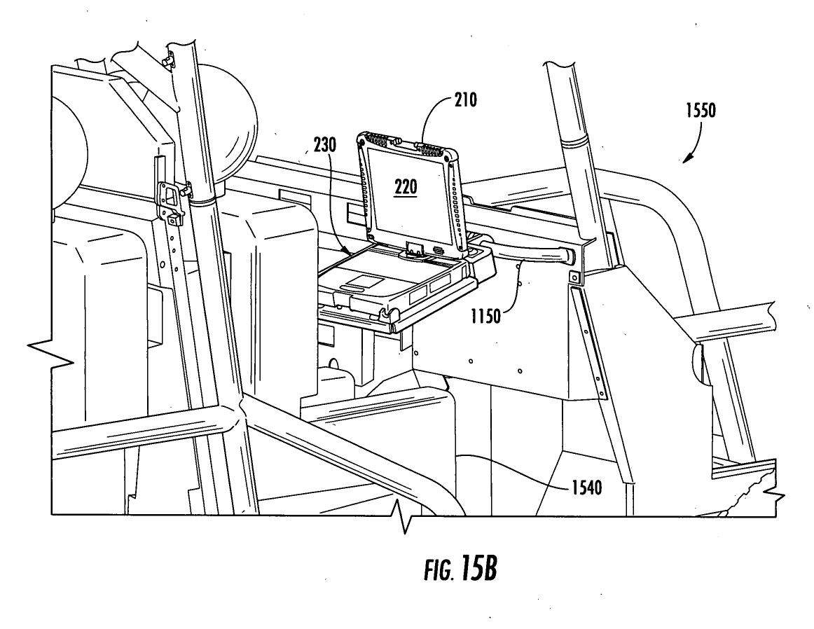

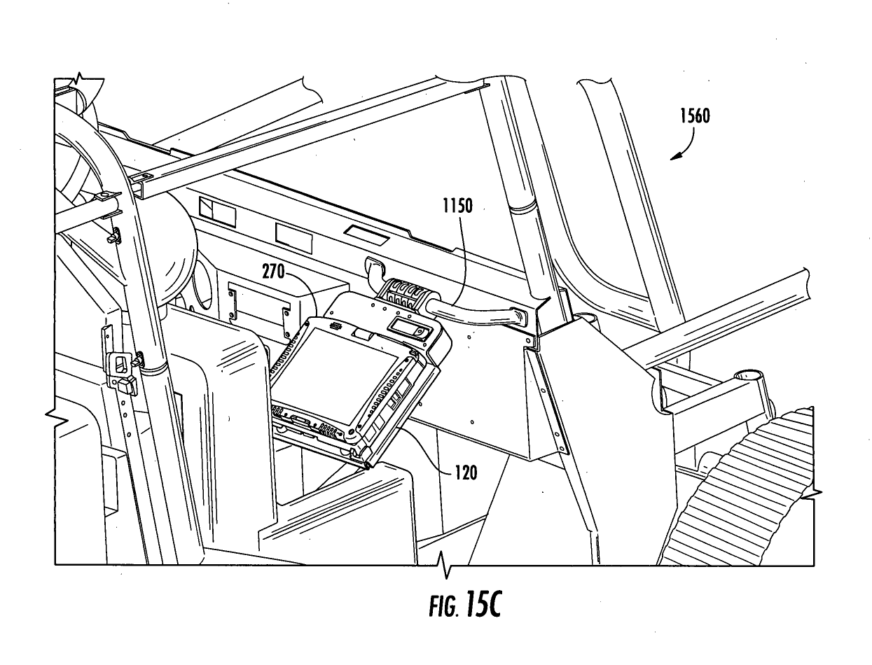

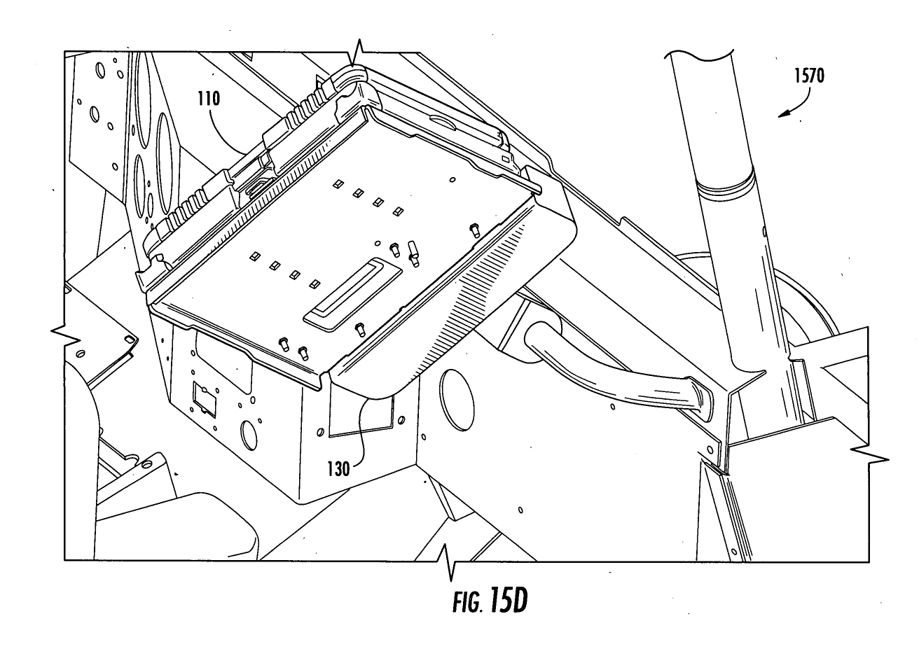

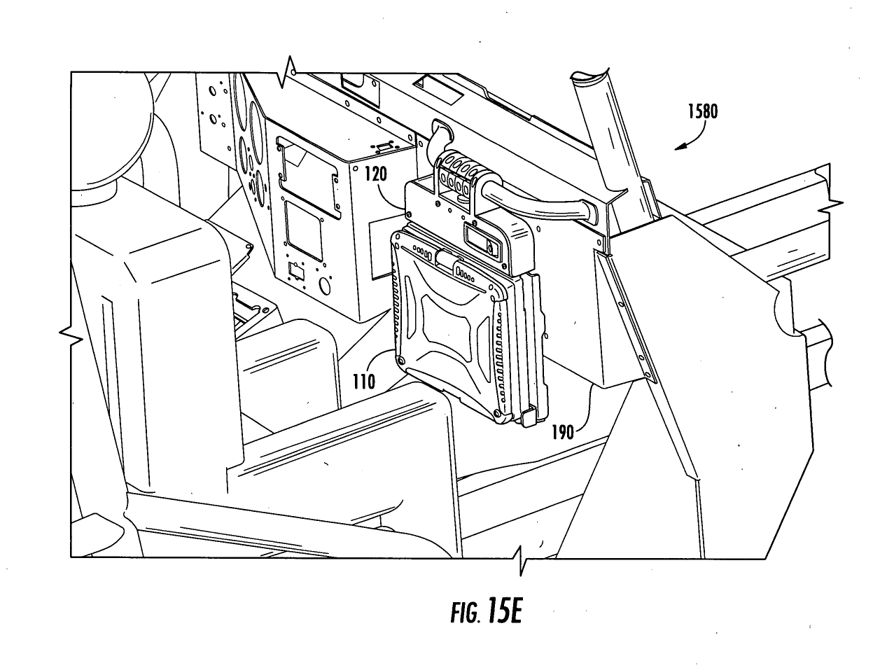

FIGS. 15A through 15E show perspective installation views of the adapter with the laptop 110 installed in an IN. The installation view 1500 in FIG. 15A shows the handlebar 1150 attached to a dashboard bracket 1510, below which is disposed a vertical dashboard plate 190. The bracket 1510 connects to the vehicle frame 1520. Flush mounts 1160 at opposite ends of the handle bar 1150 provide a surface for screw mounting to the dashboard mount 1510 of an automotive vehicle.

This assembly represents the second embodiment as a dashboard installation 1530. A passenger seat 1540 for an operating occupant is disposed aft of these components. In this view, the adapter is disposed in a first position vertically upright (e.g., +90° from horizontal, with the keyboard 230 concealed in tablet mode 270). In this manner, the laptop 110 is disposed with its display 220 facing the seat 1540.

In the FIG. 15B configuration, the perspective installation view 1550 shows the adapter for the dashboard configuration in a second position slightly depressed (e.g., −5° from horizontal with the display 220 facing substantially upward towards an occupant in the seat 1540 and the keyboard 230 exposed, having been rotated in the pitch direction 510 along the axis of the handlebar 1150 from the (first) vertical position.

In the FIG. 15C configuration, the perspective installation view 1560 shows the adapter in a third position moderately depressed (e.g.,) −20° from horizontal with the screen of the laptop 110 facing substantially upward towards an occupant in the seat 1540 and the keyboard 230 concealed (in tablet mode 270), having been pitch rotated along the axis of the handle bar 1150 from the first vertical position.

In the FIG. 15D configuration, the perspective installation view 1570 shows the adapter pivoting in the roll direction 520 via the pivot plate 1020. In the FIG. 15E configuration, the perspective installation view 1580 shows the adapter in a downward vertical position (−90° from horizontal) with the monitor 610 of the laptop 110 in stowage mode with the display 220 and keyboard 230 concealed and the adapter substantially parallel to the dashboard plate 190.

Various exemplary embodiments provide a rugged mounting solution for the Toughbook laptop 110 in a constrained location that enables the operator to easily and quickly adjust the position of the laptop 110 for use in multiple positions as in tablet mode 270 or open mode 210 with the keyboard 230, as well as enable that operator in a small vehicle, such as the ITV, to quickly move the laptop 110 out of the way of entering and exiting the vehicle.

To use the laptop 110 in a horizontal typing position 210 and in a vertical tablet position 270, the laptop 110 must rotate on the handlebar 1150 from horizontal to vertical and must also roll 180° so that the tablet 270 faces the operator. The roll mechanism represents an important feature of the adapter. This arrangement can be easily adapted for use with simpler mounting solutions.

Flanking the bolt 420, the mount plate 410 includes ball plungers that face the handlebar 1150. The dock wall 820 rotates about the bolt 420. The orifice 850 in the wall 820 includes the key-tooth 860 to prevent the dock 130 from continuing to spin. For conventional arrangements in which the laptop 110 continuously spins in the same direction, the cables get tangled during operation.

Ball detents in the collar 1170 lock the laptop 110 to 0° and 180° pitch angles. The operator merely pushes the laptop 110 in the allowable direction until the detents engage. The adapter for laptop docking rotates around the handle bar 180° with optionally four locking positions: vertical up (+90°), −5° down (slightly below horizontal), −20° down (moderately below horizontal), and vertical down)(−90°. Artisans of ordinary skill will recognize that the rotational positions are exemplary only, and not limiting. The laptop dock's outer rings, shown in IN-FL-10, enable the laptop 110 to move around the handle bar 1150.

The collar 1170 mounts between the two outer rings formed by the half-rings 1130 connect to either the block 1120 or else the flanges 1230. Holes along the cylindrical periphery of the collar 1170 are positioned at the mentioned angle increments. The plunger 1140 in the block 1120 or flange 1230 interfaces with the holes in the inner fixed shaft collar (IW-FL-11). Detents and a ball plunger on the opposite side add resistance to inhibit the laptop 110 from falling.

To rotate the laptop 110 around the transverse tube 150 or the handlebar 1150, the operator pulls the lanyard connected to the plunger 1140 which releases the collar 1170 from its prior position and then pushes the collar 1170 around the transverse tube 150 or the handle bar 1150 until the plunger 1140 locks in the next position.

This process has been adapted for the ITV-FL-05 along with the shaft collar and a modified detents plate (ITV-FL-07). The rear seats also benefit from a low-profile quick-adjust mount. By implementing the described roll mechanism along with McMaster COTS parts, the LQALM can be readily implemented in the vehicle's rear passenger section.

The height and angle of the laptop 110 depend on the position of the tubes 150 and 170, whose position can be changed by turning the knobs 440 to loosen the grip on the tubes 150 and 170, moving the laptop 110 to the desired position, and then turning the knobs 440 to lock that position.

For commercial options, a laptop platform 120 can be manufactured with simple mounting solutions in confined spaces. The conventional rugged laptop mounting solutions from Gamber-Johnson and Dodge-Ram mounts attach to the underside of their docking platform. Their main deficiency in confined spaces involves their axis of rotation and bulky mounting hardware being closer to the operator than desirable.

The LQALM mounts and rotates at the farthest position, within the vehicle, from the operator. When the LQALM is vertical, its profile is the same width as the laptop 110 and adapter. The COSTS conventional solutions cannot fold away from the operator with a comparably thin profile. The exemplary embodiments in the drawings show the laptop mounting configurations in the center console, without impeding egress and entry into the vehicle.

In a vehicle, such as an ITV, where the center console is only wide enough for one laptop 110, conventional COTS parts cannot function properly for a configuration that requires both the rear passengers have a laptop 110. The LQALM has a significantly smaller profile than COTS solutions and can be configured with various mounting solutions using McMaster parts or custom solutions for placement in multiple vehicle locations.

The ability to roll the laptop 180° with a single push, particularly for attachment to the handlebar 1150, is unique. COTS solutions typically require multiple push motions to secure a platform 120. The use of the plunger 1140 is an exemplary solution to quickly adjust the position of the laptop 110. An alternative version developed for the rear seats has the capability for multiple mounting options using the tubes 150 and 170.

Use of ITV-FL-05 and ITV-FL-06 with a modified version of IN-FL-07 along with McMaster parts provides for multiple simple configurations of the LQALM. Adding or subtracting various fittings or changing the length of the tubes simply and cheaply enables custom solutions for confined spaces.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

What is claimed is:

1. A mount for removably attaching a laptop computer to a platform in a vehicle, said computer releasably mounting to a platform, said mount comprising:
a handle that mounts to the vehicle;
an interface bay removably attaching to the platform;
a pivot plate that mounts to said bay;
a plurality of holders, each holder to wrap around said handle and attach to said pivot plate; and
a collar that releasably secures said pivot plate at an angle relative to vehicle horizontal, wherein the platform can rotate in pitch relative to said handle and can pivot in roll relative to said pivot plate.

2. The mount according to claim 1, wherein said handle attaches to a dashboard on the vehicle.

3. The mount according to claim 1, wherein said handle attaches to a front seat frame.

4. The mount according to claim 3, wherein said handle can pivot in yaw relative to said front seat frame.

5. The mount according to claim 1., wherein said collar further includes plurality of lock settings for a position for said platform oriented at one of +90°, −5°, −20° and −90° from vehicle horizontal.

6. The mount according to claim 1, wherein said plurality of holders constitutes a pair of holders that flank said collar.
